(19) United States
(12) Patent Application Publication
(10) Pub. No.: US 2005/0161813 A1
(43) Pub. Date: Jul. 28, 2005

(54) Radiation-emitting semiconductor component and method for fixing a semiconductor chip on a leadframe

(75) Inventors: Wolfgang Pammer, Regensburg (DE); Ulrich Steegmuller, Regensburg (DE); Thomas Hofer, Lappersdorf (DE); Frank Mollmer, Matting b. Pentling (DE)

Correspondence Address: COHEN, PONTANI, LIEBERMAN & PAVANE, Suite 1210, 551 Fifth Avenue, New York, NY, 10176, US

(73) Assignee: Osram Opto Semiconductors GmbH, Regensburg (DE)

(21) Appl. No.: 11/018,548

(22) Filed: Dec. 20, 2004

(30) Foreign Application Priority Data
Dec. 19, 2003 (DE) 103 59 989.4
Jan. 30, 2004 (DE) 10 2004 004 783.9

(51) Int. Cl. H01L 23/48; H01L 21/44

(52) U.S. Cl. 257/737; 438/613

(57) ABSTRACT

A radiation-emitting semiconductor component having a prefabricated composite having a leadframe (8) and a housing part (9), which is integrally formed onto the leadframe (8) and contains a plastic, and at least one semiconductor chip (1), which is fixed on the leadframe (8) of the composite with a hard solder connection (5). Furthermore, a method is disclosed for fixing semiconductor chips (1) with a hard solder on the chip mounting region (24) of a leadframe (23) with an integrally formed housing part (9) is specified.

### CROSS-REFERENCE TO RELATED APPLICATIONS

This patent application claims the priorities of German patent applications 103 59 989.4, dated Dec. 19, 2003 and 10 2004 004 783.9, dated Jan. 30, 2004, the disclosure content of which is hereby explicitly incorporated by reference into the present description.

### FIELD OF THE INVENTION

The present invention relates to a radiation-emitting semiconductor component having a prefabricated composite having a leadframe and a housing part, which is integrally formed onto the leadframe and contains a plastic, and at least one semiconductor chip, which is fixed on the leadframe of the composite, and also to a method for fixing at least one semiconductor chip on a leadframe.

### BACKGROUND OF THE INVENTION

In conventional radiation-emitting semiconductor components of this type, the semiconductor chip is often fixed on the leadframe, and electrically connected thereto, by means of a soft solder connection. Soft solders, such as, by way of example, AgSn, CuSn, PbSn or In-containing solders, are usually soldered at temperatures that are so low that no thermal deformation of the integrally formed housing part occurs. During operation of the component, however, temperatures or temperature fluctuations may occur, in particular in the region of the semiconductor chip, which may be formed as a high-power semiconductor chip, and may increase the risk of fatigue in the soft solder connection and consequently reduce the cycle stability of the component.

Hard solders, by contrast, generally have a higher cycle stability, which is advantageous particularly in the case of high-power laser chips, during cw (continuous wave) operation or pulsed operation. However, if a hard solder is used for fixing the semiconductor chip, then the integrally formed housing parts are often not dimensionally stable with respect to the higher soldering temperatures, of for example 280° C. or higher, with the result that the housing parts are not integrally formed onto the leadframe until after the soldering process and often in cost-intensive individual device processing steps.

It is often the case that, for efficiency or cost reasons, by way of example, a plurality of mounted semiconductor chips, such as, for instance, laser diode bars mounted on copper blocks, are assembled to form stacks and are provided with a common housing or arranged in a common housing. A laser diode bar is a laser component comprising a plurality of semiconductor laser bodies, in particular bodies which are formed according to an edge emitting laser diode structure, such bodies being arranged laterally beside one another on a common carrier, e.g. the epitaxy substrate of a layer sequence, from which the bodies may be formed. Details of laser bar diodes are provided in Roland Diehl, “High-Power Diode Lasers”, published by Springer, pages 173-223, which is hereby incorporated by reference. Laser diodes are available from OSRAM as part no. SPL BG81-9S and SPL BG81-2S. In a module with a plurality of semiconductor chips formed in this way, the risk of the entire module becoming unusable when one semiconductor chip fails may be increased and, consequently, it may be necessary to exchange the entire module, including semiconductor chips that are still functional, in principle, or to replace individual semiconductor chips in a complicated manner.

### SUMMARY OF THE INVENTION

One object of the invention is to provide a radiation-emitting semiconductor component which has an increased reliability and can be produced in a simplified manner.

A further object of the invention is to provide a simplified method for fixing a semiconductor chip on a leadframe.

This and other objects are attained in accordance with one aspect of the invention directed to a radiation-emitting semiconductor component comprising a prefabricated composite having a leadframe and a housing part, which is integrally formed onto the leadframe and contains a plastic, and at least one semiconductor chip, which is fixed on the leadframe of the composite by means of a hard solder connection.

The prefabricated composite having a leadframe and an integrally formed housing part permits a simplified handling of the semiconductor component, particularly during its production or later applications. Thus, a semiconductor component of this type can be produced in a process that does not require any individual processing steps, such as integrally forming a housing part onto the leadframe of the semiconductor component after the fixing of the semiconductor chip on the leadframe.

The integrally formed housing part advantageously protects the radiation-emitting semiconductor component, in particular the semiconductor chip, against harmful external influences, such as mechanical loads, for instance.

It should be noted that single-part housings are also regarded as a housing part within the scope of the invention, with the result that it is possible to fit a housing for the semiconductor chip even before the fixing thereof on the leadframe by means of a hard solder connection.

The hard solder connection has a generally higher cycle stability compared with a soft solder connection, even at high operating temperatures, of for example 250° C. or more, with the result that the risk of fatigue in the connection can advantageously be reduced and the reliability of the semiconductor component can advantageously be increased.

Preferably, the semiconductor chip is electrically conductively and/or thermally conductively connected to the leadframe via the hard solder connection. In particular, a hard solder containing AuSn and/or a metallic leadframe, for example containing Cu, is suitable. An electrically conductive connection to the leadframe that is necessary in addition to the hard solder connection can thus advantageously be dispensed with since the semiconductor chip can be electrically contact-connected at least partly via the hard solder connection and the leadframe.

The semiconductor chip preferably contains at least one II-V semiconductor material, comprising InₓGa_{y}Al_{1-x-y}P, InₓGa_{y}Al_{1-x-y}N or InₓGa_{y}Al_{1-x-y}As, where in each case 0≦x≦1, 0≦y≦1 and x+y≦1.

Particularly for a semiconductor chip in the form of a laser chip or laser diode bar, which generate a large amount of heat during operation, a hard solder connection is advantageous on account of its relatively high stability with regard to temperature fluctuations. A hard solder connection is particularly advantageous for high-power laser chips or laser diode bars, having powers of, for example, 20 W or higher.

The housing part can be integrally formed onto the leadframe by means of an injecting molding, compression molding or transfer molding process. These are methods suitable for producing radiation-emitting semiconductor components according to the invention in large numbers. An individual processing process of the individual components, such as, for instance, integrally forming the housing part after the fixing of the chip on the leadframe, can advantageously be dispensed with.

In one embodiment of the invention, the housing part surrounds the leadframe in such a way that the protection of the semiconductor component is improved and/or the housing part integrally formed onto the leadframe is mechanically stabilized.

The housing part can be produced from a material that is essentially dimensionally stable at temperatures corresponding to the melting point or melting range of the hard solder connection. This temperature is 280° C. or higher, such as 300° C., for instance, by way of example in the case of hard solder connections containing AuSn. This ensures the dimensional stability of the housing part if it is thermally conductively connected to the hard solder during the hard soldering process. A dimensional stability of the housing part at temperatures of 25° C. or more above the melting point of the hard solder connection may often also be necessary to avoid a disadvantageous incipient melting of the integrally formed housing part.

Furthermore, the housing part can have high dimensional stability, in particular with respect to high temperatures or temperature fluctuations, and/or contains at least one plastic, which can also be used in the abovementioned molding methods and/or is dimensionally stable at the abovementioned temperatures. Plastics containing PEEK (polyetherether ketones) may be used in this case, by way of example.

In a further preferred embodiment, the semiconductor chip is arranged on a, preferably electrically conductive, heat sink, for example containing CuW, which advantageously improves the heat dissipation from the semiconductor chip. This reduces the risk of a failure of the semiconductor component owing to a high evolution of heat in the region of the semiconductor chip. The semiconductor chip can be arranged and/or affixed on the heat sink by means of the hard solder connection. The heat sink can be arranged between the semiconductor chip and the leadframe. The heat sink may be connected to the leadframe by means of a connecting means, for instance a hard solder or a soft solder. A soft solder may suffice in this case since the heat sink distributes the heat arising at the semiconductor chip during operation over a relatively large area, as a result of which disadvantageous fatigue phenomena of the soft solder can be avoided or reduced compared with an arrangement of the soft solder directly at the semiconductor chip. Consequently, the cycle stability of the radiation-emitting semiconductor component is advantageously not significantly reduced by a soft solder connecting means. In this case, the semiconductor chip is preferably firstly fixed on the heat sink by the hard solder connection, said heat sink subsequently being connected to the leadframe by means of a soft solder connecting means.

However, a hard solder, which may contain AuSn, for example, likewise can serve as connecting means between heat sink and leadframe. In addition to the fundamentally higher cycle stability, this also advantageously simplifies the production of the radiation-emitting semiconductor component since it is thus possible to carry out the soldering processes of the semiconductor chip onto the heat sink and the heat sink onto the leadframe in one method step. A soft solder that possibly melts at high hard soldering temperatures then does not have to taken into consideration.

In one embodiment, the hard solder participating in the hard solder connection and the connecting means at least approximately have the same melting point, which can be at a temperature that is as low as possible in order that the thermal stress of the radiation-emitting semiconductor component, in particular of the integrally formed housing part, is not increased unnecessarily. Furthermore, the fixing of the semiconductor chip on the heat sink and of the heat sink on the leadframe may be carried out in one method step.

In a further embodiment, the radiation-emitting semiconductor component comprises a housing, preferably for protecting the semiconductor chip against harmful external influences. The housing comprises the housing part integrally formed onto the leadframe, and at least one further additional housing part, for example containing a plastic, a metal or steel.

The housing parts may be mechanically connected to one another and/or to the leadframe by way of example by means of a fixing device, for instance a latching device or an adhesive. An additional encapsulation of the semiconductor chips, such as with silicone, for instance, which may exert disadvantageous pressure on the semiconductor chip and be subjected to rapid aging in the case of high-power chips, in particular laser diode chips or laser diode bars, can thus advantageously be dispensed with without increasing the risk of harmful external influences acting on the semiconductor chip.

Furthermore, the housing can have a radiation-transmissive window. The semiconductor chip can be surrounded completely by the protective housing. The housing may also comprise the leadframe in addition to the integrally formed and the additional housing part.

In a further embodiment, an optical element, for example a lens, a waveguide, such as, for instance, an optical waveguide, or a fiber is arranged downstream of the semiconductor chip. The lens may serve for example for concentrating the radiation generated by the semiconductor chip, and the optical waveguide may serve for feeding the radiation generated by the semiconductor chip to a laser that is to be pumped with said radiation. The optical element can be at least partly surrounded by the housing of the radiation-emitting component or arranged therein.

Another aspect of the present invention is directed to a method for fixing at least one semiconductor chip on a leadframe, in which at least one housing part is integrally formed onto a leadframe comprising a chip mounting region. Afterward, the semiconductor chip is fixed on the chip mounting region by means of a hard solder. A housing part that is integrally formed onto a leadframe prior to chip mounting is often referred to as “premolded”.

The housing part can be integrally formed by means of an injection molding, compression molding or transfer molding method, using a plastic that is essentially dimensionally stable with respect to the temperatures that occur during the subsequent hard soldering. What can be achieved by virtue of the dimensionally stable plastic is that the housing part, in the case of a thermally conductive connection between the hard solder and the housing part, is essentially not damaged by the high temperatures that often occur in particular during the hard soldering process.

The leadframe with the integrally formed housing part can be formed in such a way that terminals are assigned to the chip mounting region for electrically contact-connecting the chip, which are at least partly electrically conductively connected thereto or can be conductively connected to the semiconductor chip in a further method step, for example via a bonding wire. The housing part can be at least partly formed around the terminals. This has the advantage of increasing the stability of the leadframe with the integrally formed housing part. Furthermore, it is thus also possible to mechanically stabilize terminals that are initially not electrically or mechanically connected to the leadframe.

At least one fixing device can be provided at the housing part or the chip mounting region, which fixing device mechanically stabilizes the housing part or facilitates the fitting of an additional housing part.

The semiconductor chip may be formed as a radiation-generating semiconductor chip, preferably as an LED chip, laser diode chip or laser diode bar.

In another embodiment, at least one additional housing part is arranged around the semiconductor chip, and, together with the integrally formed housing part and possibly the leadframe, may form a housing that protects the semiconductor chip against harmful external influences.

In a further embodiment, a plurality of semiconductor chips are fixed on a respectively assigned leadframe, the leadframes being connected to form a leadframe strip. In the course of being integrally formed, a housing part is preferably integrally formed onto essentially each chip mounting region of the leadframes of the leadframe strip, with the result that the chip mounting region, in particular the semiconductor chip that is subsequently fixed thereon by means of the hard solder on the chip mounting region, enjoys an advantageous mechanical protection.

In another embodiment, this structure with semiconductor chips, chip mounting regions and housing part(s) on the leadframe strip is singulated into semiconductor components. In this case, the additional housing part may be fitted before or after singulation into semiconductor components.

A method of this type has the advantage that housing parts which are dimensionally stable with respect to the temperatures occurring during hard solder processes can be integrally formed onto a leadframe strip. Furthermore, radiation-emitting semiconductor components with integrally formed housing parts can thus be produced in a cost-effective and efficient manner by fixing semiconductor chips on leadframes on a leadframe strip by means of a hard solder, it being possible for the housing part to be dimensionally stable with respect to the hard soldering temperatures.

A semiconductor component made in accordance with the invention is particularly suitable for being used in a module. In particular, modules having a plurality of semiconductor chips can thus be produced in a cost-effective manner, it being possible for each semiconductor chip to comprise a leadframe with an integrally formed housing part and terminals, with the result that when a semiconductor chip fails, it is advantageous that it is not necessary for the entire module to be exchanged or a semiconductor chip to be replaced in a complicated manner. Rather, it is possible to remove a defective semiconductor chip with housing and replace it by a functional semiconductor component.

The radiation-emitting semiconductor components described above and in the exemplary embodiments below are preferably produced by application of the above method, with the result that the features of the semiconductor components may also relate to the above method, and vice versa.

### BRIEF DESCRIPTION OF THE DRAWINGS

FIG. 1 shows a schematic sectional view of a first exemplary embodiment of a radiation-emitting semiconductor component according to the invention,

FIGS. 2A and 2B show, respectively, a perspective oblique view and a schematic sectional view of a second exemplary embodiment of a radiation-emitting semiconductor component according to the invention, and

FIGS. 3A, 3B and 3C show a schematic illustration of a method sequence according to the invention for fixing a semiconductor chip on a leadframe strip on the basis of three intermediate steps.

### BRIEF DESCRIPTION OF THE DRAWINGS

Elements that are of the same type or act identically have the same reference symbols in the figures.

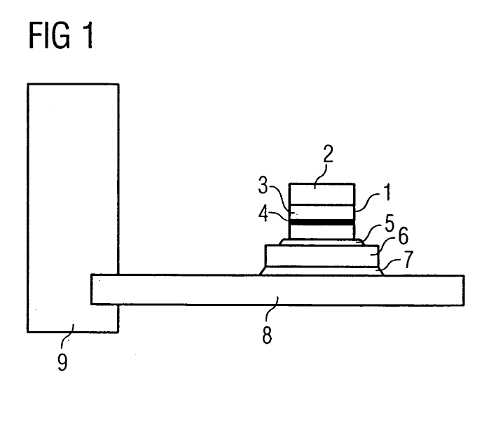

FIG. 1 illustrates a schematic sectional view of a first exemplary embodiment of a radiation-emitting semiconductor component according to the invention.

A semiconductor chip 1, comprising a semiconductor layer sequence 3—arranged on a substrate 2—with a radiation-generating active zone 4, is fixed on a heat sink 6, preferably containing CuW, by means of a hard solder 5, for example containing AuSn. The heat sink 6 dissipates the heat rising at the semiconductor chip, preferably via the leadframe 8, and thus advantageously reduces the risk of a failure of the semiconductor chip 1 during operation of the component. The heat sink 6 is preferably adapted to the semiconductor chip 1 with regard to its thermal expansion and is fixed on a leadframe 8, for instance containing a metal such as Cu, by means of a second solder 7, for example containing a hard solder such as AuSn. Before the semiconductor chip 1 was fixed on the leadframe 8, a housing part 9 was integrally formed onto the latter, said housing part containing a plastic that is essentially dimensionally stable with respect to the temperatures occurring during soldering, such as PEEK, for instance, or a correspondingly formed LCP (Liquid Crystal Polymer). The housing part 9 preferably at least partly surrounds the leadframe 8, or is mechanically stably connected thereto in a different way and may be produced for example by means of an injection molding, transfer molding or compression molding process. The semiconductor chip 1 is connected to the leadframe 8 by means of the solders 5 and 7 and the heat sink 6, this connection advantageously having a high mechanical stability and simultaneously serving as an electrically conductive connection.

In this exemplary embodiment, the semiconductor chip 1 is formed as a high-power laser chip which, by way of example, contains InₓGa_{y}Al_{1-x-y}As, where 0≦x≦1, 023 y≦1 and x+y≦1, and has an emission wavelength in the infrared spectral range, and/or a power of 25 W or more. The hard solder 5 and the solder 7 preferably have approximately the same melting points, it being possible for the solder 7 likewise to be formed as a hard solder, with the result that it is possible to carry out the fixing of the semiconductor chip onto the heat sink 6 and of the latter onto the leadframe 8 in one step. The connection of the semiconductor chip 1 to the heat sink 6 is in this case distinguished by an advantageously high cycle stability.

The heat required for melting the solders is preferably supplied during production from that side of the leadframe 8 which is opposite to the semiconductor chip 1, and at a distance from the housing part 9 being as great as possible, in order to avoid an unnecessary thermal loading of the housing part 9. The semiconductor chip 1 is therefore advantageously arranged at a distance from the housing part 9 being as great as possible.

Temperatures of approximately 310° C. are reached at least briefly during the soldering process, the housing part 9 advantageously being essentially dimensionally stable at said temperatures. Since the housing part 9 is already integrally formed before the soldering process, the semiconductor chip is already protected against harmful external influences by the housing part during further process steps—which are carried out after fixing on a leadframe strip.

In this example, the semiconductor chip 1 is fixed “upside down” on the heat sink 6 with the substrate 2 on that side of the active zone which is remote from the leadframe 8, as a result of which the stability of the structure with semiconductor chip 1 and heat sink 6 can advantageously be increased compared with an “upside up” arrangement, in which the substrate would be arranged between the active zone 4 and the heat sink 6.

In the material system InₓGa_{y}Al_{1-x-y}As, the semiconductor chip often comprises a GaAs substrate, the coefficient of thermal expansion of which may be 6 ppm/K, by way of example. A CuW-containing heat sink, by way of example, may be adapted to this coefficient of expansion during its production, for instance by varying the Cu or W proportion. The coefficient of expansion of the heat sink is then advantageously likewise 6ppm/K in the case of an “upside up” arrangement. It goes without saying that a CuW-containing heat sink can also be realized with other coefficients of expansion which are advantageously adapted or are formed in adapted fashion to those of the material adjoining the heat sink on the part of the semiconductor chip.

A radiation-emitting component of this type can be produced in a simplified and cost-effective manner with high cycle stability since the housing part is essentially dimensionally stable at the temperatures that occur during the soldering process, and can thus be integrally formed onto the leadframe actually before the semiconductor chip is fixed on the latter.

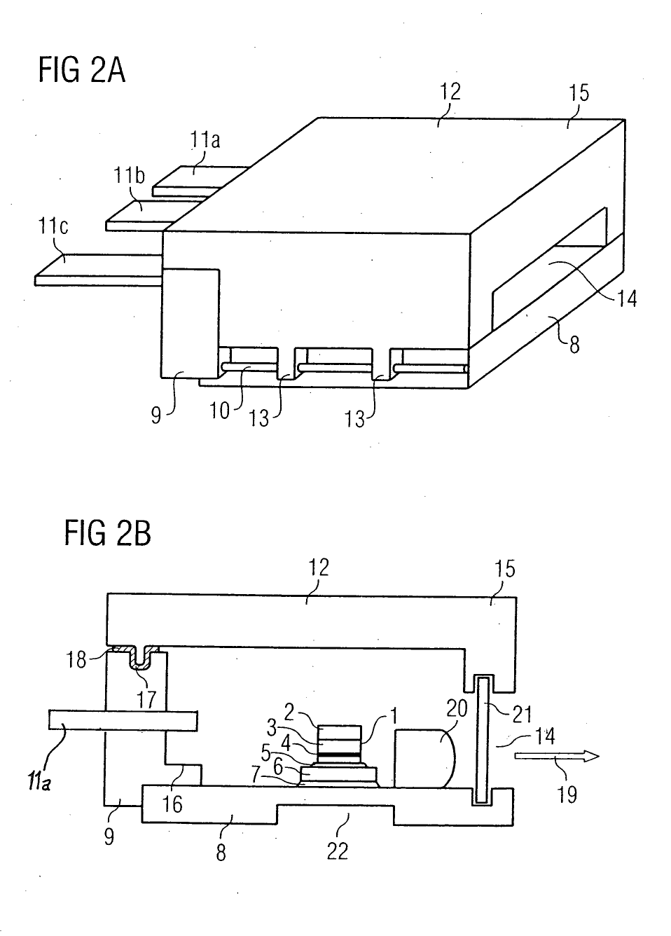

FIGS. 2A and 2B schematically illustrate a second exemplary embodiment of a radiation-emitting semiconductor component according to the invention. A perspective oblique view as shown in FIG. 2A and a sectional view is shown in FIG. 2B.

Terminals 11A, 11B and 11C serve as electrical contacts to the semiconductor component. Since the terminals serve for contact connection, at least one of them is not electrically connected to the leadframe 8. If all of them were electrically connected to the leadframe, contact connecting the laser diode would result in a short circuit. In the production of components of this kind according to the prior art, the laser diode, which is arranged on a leadframe (said leadframe having no housing part integrally formed thereon) is at first contact connected so that both contacts of the diode are connected to the leadframe terminals. During this procedure a first terminal is connected to a first contact and a second terminal is connected to a second contact. The leadframe and all of the terminals are thus electrically and mechanically connected, such that a short circuit would arise if this component were operated. Afterward, the electrical and mechanical connection of at least one terminal to the leadframe is broken, e.g. by embossing. The separated terminal has to be externally mechanically stabilized. The contact connection of the component with the terminals may also be carried out after the separation of the terminal from the leadframe. Afterward, the housing of the component is provided. These steps are known to any person ordinarily skilled in the art, as well as the fact that there is a need to mechanically stabilize the separated terminal. In accordance with the invention, however, a housing part is integrally formed onto the leadframe before the chip is mounted, such that the housing part can stabilize a terminal, which is intended to be separated from the leadframe, by being formed around it, preferably before separation. External stabilization of a terminal can, thus, be dispensed with.

In particular, the structure shown in FIG. 2A with a leadframe 8 and the housing part 9 integrally formed onto the latter is mechanically stabilized by a fixing device 10, at which the housing part 9 is arranged. The fixing device 10 is preferably arranged at the leadframe 8 or formed in the leadframe, for example in the form of a latching device such as a suitable bulge or indentation. Compared with the component illustrated in FIG. 1, it is thus possible to reduce the contact area between leadframe 8 and housing part 9 and thus the thermal loading of the housing part 9. By virtue of the fact that the housing part 9 at least partly surrounds the terminals 11a, 11b and 11c, which serve for electrically contact-connecting the component and can be mechanically and/or electrically connected to the leadframe, the stability of this structure is increased. Any further details are readily apparent to anyone with ordinary skill in the art and, thus, need not be provided here. A higher stability of the structure with housing part and leadframe advantageously reduces the effects of harmful external influences on a semiconductor chip arranged on the leadframe 8.

In this exemplary embodiment, the fixing device 10 is also formed for fixing an additional housing part 12, which contains for example a metal such as, for instance, Al, steel or a plastic such as PEEK or a suitably formed LCP, by means of fixing means 13 provided on said part, for example grids, which are suitable for the fixing device 10. The additional housing part 12 has a window 14 through which the radiation generated by a semiconductor chip arranged on the leadframe 8 can leave the housing 15 of the radiation-emitting semiconductor component, which housing is formed by the housing parts 9 and 12 and the leadframe 8. The housing 15 thus formed more extensively reduces the risk of damage to the semiconductor chip 1.

FIG. 2B shows a schematic sectional view of the component illustrated in FIG. 2A. The housing part 9 integrally formed onto the leadframe has a projection 16, which is in mechanical contact with the leadframe 8. The additional housing part 12 is connected to the housing part 9 by means of a connecting device 17 comprising, by way of example, a recess in the housing part 9 and a bulge formed in a manner corresponding to said recess in the additional housing part 12, at which a connecting means 18, for example an adhesive, is arranged, by means of which the housing part 9 can be mechanically connected to the additional housing part 12.

An optical element 20 and a radiation-transmissive window layer 21 are arranged in the beam path of the radiation 19 generated by the semiconductor chip 1, which is formed as a laser diode bar, by way of example. In this exemplary embodiment, the optical element 20 is formed as a lens which is arranged and/or fixed on the leadframe 8, as illustrated. In a departure from this, the optical element 20 may, for example, also be arranged and/or fixed on the heat sink 6. It goes without saying that this arrangement can also be realized with a plurality or other optical elements, in particular those mentioned further above or below.

As in the exemplary embodiment illustrated in FIG. 1, the semiconductor chip 1 comprises a substrate 2, a semiconductor layer sequence 3 and an active zone 4 and is arranged on a heat sink 6 by means of a hard solder 5 and said heat sink is arranged on the leadframe 8 by means of a second solder 7. The chip is thus preferably electrically conductively connected to the leadframe 8. On that side of the leadframe 8 which is opposite to the semiconductor chip 1, a cooling structure 22 is provided, for example in the form of cooling channels, preferably milled into the leadframe, which permit efficient liquid cooling, or a recess in the leadframe, in which, by way of example, a heat sink element can be arranged. In the same way as a cooling liquid, the heat sink element, for example a Cu block, is preferably thermally well linked to the leadframe or connected thereto.

One of the terminals, preferably a terminal which is separated from the leadframe, is connected via a bonding wire with the side of the chip which is arranged opposite from the leadframe or the heatsink. This terminal may project through the housing part 9, to facilitate the connection with the bonding wire. The remaining second diode contact may be effected by means of the leadframe.

Stated another way, the electrical contact-connection of the semiconductor chip 1 may be effected, for example, via the leadframe and one or a plurality of bonding wires (not illustrated) which are preferably electrically conductively connected to the semiconductor chip on that side thereof which is opposite to the heat sink and at least one of the terminals 11a, 11b or 11c shown in FIG. 2A. In this case, the connection is expediently effected within the housing 15, in which the terminals can be connected from the semiconductor chip 1 for example in regions not covered by the housing part 9 or through other suitable formations. Preferably, the bonding wire is connected to the terminal before the additional housing part 12 is fitted.

Preferably, the terminals 11a and 11c are formed for a bonding wire connection to the semiconductor chip 1 and, consequently, are not electrically conductively connected to the leadframe 8. This is advantageous in the case of high-power laser diode bars, by way of example, during the operation of which high currents flow which can thereby be distributed between a plurality of terminals and/or bonding wires. The terminal 11b is electrically conductively connected to the leadframe 8 and advantageously mechanically stabilizes the integrally formed housing part 9, which in turn preferably mechanically stabilizes the terminals 11a and 11c. For example two terminals 11a and 11c may be seperated from the leadframe for a connection to the chip via bonding wires. The remaining terminal 11b may be electrically and mechanically connected to the leadframe. In this way the housing part, which is formed around this terminal is stabilized due to the mechanical interconnection of the terminal to the leadframe. The leadframe and this terminal may be formed as a single piece. Terminals 11a and 11c which are separated from the leadframe are mechanically stabilized by means of the housing part being formed around them. Separation is preferably conducted after the housing part is provided.

The projection 16 advantageously increases the stability of the structure with leadframe 8 and housing part 9 in particular with respect to mechanical force effects and with the cooperation of the fixing device 10 from FIG. 2A.

In addition to the leadframe 8 and the housing parts 9 and 12, the window layer 21, which may be provided with an antireflection coating with regard to the radiation generated by the semiconductor chip, is part of the housing 15 of the radiation-emitting semiconductor component which essentially completely surrounds the semiconductor chip. This housing 15 improves the protection of the semiconductor chip 1 with regard to harmful influences that can act on the semiconductor chip 1 from the window 14.

The cooling structure 22 enables improved dissipation of heat from the semiconductor chip 1 via the heat sink 6 and the leadframe 8, as a result of which, in an advantageous manner, the efficiency of the component can be increased and the risk of a failure can be reduced. A cooling structure of this type may be milled into the leadframe 8, by way of example. It goes without saying that the cooling structure 22 may have a form that deviates from the essentially rectangular cross section illustrated.

The emission characteristic of the semiconductor chip 1 may be influenced by means of the optical element 20, such as, for instance, by collimation of the radiation by means of a lens or other beam shaping elements which may serve for example for beam homogenization or wavelength stabilization, such as a holographic bragg grating (HBG) for instance. In the case of laser diode chips or bars, for instance, it is possible to reduce the divergence of the emitted laser radiation. Since the divergence of the laser radiation, particularly in the case of edge-emitting lasers, may be different in different spatial directions, by way of example an FAC (fast axis collimation) lens is used for more highly divergent radiation and an SAC (slow axis collimation) lens is used for less divergent radiation.

Optical elements of this type may contain GaP, for example, which constitutes a suitable material for a lens, preferably a lens having a high refractive index, particular for wavelengths of 800 nm or higher. In a departure from the illustration, the optical element may also be arranged in the window. In particular, the optical element may comprise the window layer.

Overall, in the same way as the component shown in FIG. 1, the exemplary embodiment of the invention illustrated in FIGS. 2A and 2B can be produced in a simplified manner and additionally has a housing that can protect the semiconductor chip on all sides against harmful external influences. This housing may already be formed while the leadframe is still part of a leadframe strip, as a result of which a very good protection of the semiconductor chip may already be ensured during the further processing of the leadframe strip. A housing of this type may advantageously be formed such that it is essentially tight with respect to dust particles.

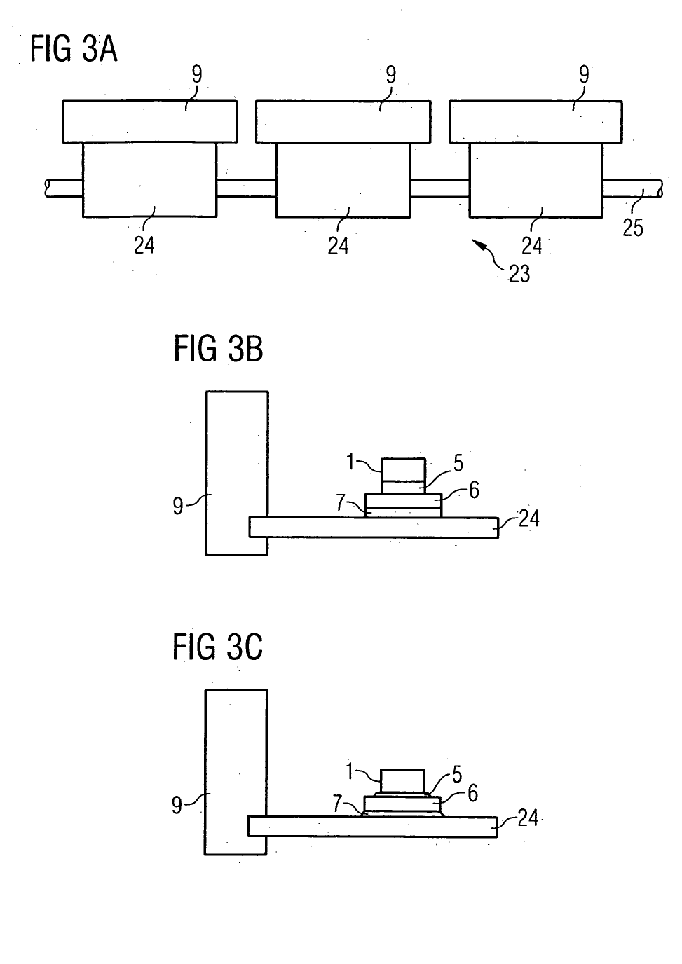

FIG. 3 schematically illustrates an exemplary embodiment of a method according to the invention for fixing a semiconductor chip on a leadframe strip on the basis of the intermediate steps shown in a plan view in FIG. 3A and sectional views in FIGS. 3B and 3C.

FIG. 3A shows a schematic plan view from above of a leadframe strip 23 comprising a plurality of chip mounting regions 24 that are connected via a schematically illustrated connecting strip 25. The chip mounting regions 24 preferably contain Cu and may be part of a leadframe, for example of the TO 220 or TO 263 type, which are particularly widespread for application in high-power semiconductor chips. A housing part 9 integrally formed onto a leadframe strip prior to chip mounting is often referred to as “premolded”.

In a first method step, a housing part 9 is integrally formed onto the chip mounting regions 24, preferably by means of injection molding. The housing part 9 preferably contains a plastic, particularly preferably a plastic that is dimensionally stable with respect to high temperatures, such as PEEK, for example, which may be essentially dimensionally stable up to approximately 340° C. The housing part 9 is connected to the chip mounting region 24 preferably in a mechanically stable manner, for example by means of a fixing device 10 as shown in FIG. 2A or by being at least partly formed around the chip mounting region 24 in the manner illustrated here, thereby facilitating the further processing of the structure illustrated.

Afterward, a semiconductor chip 1, for example a high-power laser diode chip or bar, is positioned by means of a hard solder material 5, for example containing AuSn, on a heat sink 6, for example containing CuW, and the latter is in turn positioned by means of a further solder material 7, preferably likewise containing a hard solder material, for example AuSn, on the chip mounting region 24 in such a way that the heat sink 6, as is shown in FIG. 3B on the basis of a schematic sectional view, is arranged between the chip mounting region 24 and the semiconductor chip 1.

The solders 5 and 7, which preferably have approximately the same melting point or melting range, for example approximately 280° C. to 310° C. in accordance with an AuSn solder, are thereupon melted in a further method step with a temperature increase. In this case, the necessary supply of heat is preferably effected via that surface of the chip mounting region 24 which is opposite to the semiconductor chip 1. Preferably, the distance between the semiconductor chip 1 and the housing part 9 is in this case chosen to be as large as possible in order that the thermal loading of the housing part 9 is kept as low as possible. Afterward, the supply of heat is ended and the molten solders 5 and 7 can solidify, which is illustrated by the expanded side edges of the solders 5 and 7 in FIG. 3C.

The semiconductor chip 1 is thus fixed on the chip mounting region 24, which may be part of a leadframe, and is preferably electrically and/or thermally conductively connected thereto via the solders 5, 7 and the heat sink 6.

A method of this type has the advantage that semiconductor chips can be fixed on a chip mounting region onto which a housing part, in particular a plastic-containing housing part, has been integrally formed beforehand, by means of a hard solder, since the housing part is dimensionally stable with respect to the temperatures required for hard soldering. The hard solder connection is distinguished by a high cycle stability relative to other connecting means, such as a soft solder connection, for example. This advantageously increases the reliability of a radiation-emitting semiconductor component produced using this method.

A further advantage of the method is that it permits the production of large numbers of components with a housing part integrally formed onto the chip mounting region and hard-soldered semiconductor chips. The components can be provided with a protective housing, as shown for example in FIG. 2A, while still joined together with the leadframe strip, as a result of which it is possible to avoid expensive individual device processing steps such as subsequent encapsulation of the leadframe with a housing by injection molding.

The scope of protection of the invention is not limited to the examples given herein above. The invention is embodied in each novel characteristic and each combination of characteristics, which particularly includes every combination of any features which are stated in the claims, even if this feature or this combination of features is not explicitly stated in the claims or in the examples.

1. A radiation-emitting semiconductor component having a prefabricated composite having a leadframe (8) and a housing part (9), which is integrally formed onto the leadframe (8) and contains a plastic, and at least one semiconductor chip (1), which is fixed on the leadframe (8) of the composite by means of a hard solder connection (5).

2. The radiation-emitting semiconductor component as claimed in claim 1, wherein the semiconductor chip (1) is electrically conductively connected to the leadframe (8) via the hard solder connection (5).

3. The radiation-emitting semiconductor component as claimed in claim 1, wherein the housing part (9) at least partly surrounds the leadframe (8).

4. The radiation-emitting semiconductor component as claimed in claim 1, wherein the housing part (9) is produced in an injection molding, compression molding or transfer molding processs.

5. The radiation-emitting semiconductor component as claimed in claim 1, wherein the housing part (9) is dimensionally stable at a temperature corresponding to the melting point of the hard solder connection (5).

6. The radiation-emitting semiconductor component as claimed in claim 1, wherein the semiconductor chip (1) is a laser diode chip or a laser diode bar.

7. The radiation-emitting semiconductor component as claimed in claim 1, wherein the semiconductor chip (1) is arranged by means of the hard solder connection (5) on a heat sink (6) arranged between the semiconductor chip (1) and the leadframe (8).

8. The radiation-emitting semiconductor component as claimed in claim 7, wherein the heat sink (6) is arranged on the leadframe (8) by means of a connecting means (7).

9. The radiation-emitting semiconductor component as claimed in claim 8, wherein the connecting means (7) is a hard solder or a soft solder.

10. The radiation-emitting semiconductor component as claimed in claim 1, wherein the semiconductor chip (1) is arranged in a housing (15) comprising the housing part (9) and at least one additional housing part (12).

11. The radiation-emitting semiconductor component as claimed in claim 10, wherein an optical element (20) is arranged within the housing (15).

12. A method for fixing at least one semiconductor chip (1) on a leadframe (8), having the steps of:
a) integrally forming at least one housing part (9) onto a leadframe (8) comprising a chip mounting region (24);
b) fixing the semiconductor chip (1) on the chip mounting region (24) by means of a hard solder.

13. The method as claimed in claim 12, wherein the housing part (9) is integrally formed by means of an injection molding, compression molding or transfer molding process.

14. The method as claimed in claim 12, wherein the housing part (9) contains a plastic.

15. The method as claimed in claim 12, wherein the housing part (9) contains PEEK.

16. The method as claimed in claim 12, wherein the housing part (9) is thermally conductively connected to the hard solder (5) during the hard soldering process.

17. The method as claimed in claim 12, wherein temperatures of above 280° C., preferably of above 300° C., occur during the hard soldering process.

18. The method as claimed in claim 12, wherein terminals (11a, 11b, 11c) are assigned to the chip mounting region (24) for contact-connecting the semiconductor chip (1).

19. The method as claimed in claim 18, wherein the housing part (9) is at least partly formed around the terminals (11a, 11b, 11c).

20. The method as claimed in claim 12, wherein the semiconductor chip (1) is arranged on a heat sink (6) by means of a hard solder connection (5).

21. The method as claimed in claim 20, wherein the heat sink (6) is arranged on the chip mounting region (24) by means of a connecting means (7) in such a way that the heat sink (6) is arranged between the semiconductor chip (1) and the chip mounting region (24).

22. The method as claimed in claim 21, wherein the connecting means (7) is a hard solder or a soft solder.

23. The method as claimed in claim 21, wherein the hard solder and the connecting means (7) have at least approximately the same melting point.

24. The method as claimed in claim 21, wherein the arranging of the semiconductor chip (1) on the heat sink (6) by means of the hard solder and the arranging of the heat sink (6) on the chip mounting region (24) by means of the connecting means (7) are effected in one process step, in particular simultaneously.

25. A method for fixing a plurality of semiconductor chips (1) on a respectively assigned leadframe as claimed in claim 12, wherein the leadframes are connected to one another in the form of a leadframe strip (23).

26. The method as claimed in claim 25, wherein the fixing of the semiconductor chips (1) on the respectively assigned leadframe (8) of the leadframe strip (23) is followed by singulation into semiconductor components, respectively comprising at least one semiconductor chip (1), at least one chip mounting region (24) and a leadframe (8) with an integrally formed housing part (9).

27. The method as claimed in claim 25, wherein the leadframe strip (23) comprises a plurality of leadframes (8) formed in uniform fashion.
